(19) United States
(12) Patent Application Publication
(10) Pub. No.: US 2018/0090957 A1
(43) Pub. Date: Mar. 29, 2018

(54) POWER BANK WITH FAN FOR COOLING

(71) Applicant: BINDU RAMA RAO, LAGUNA NIGUEL, CA (US)

(72) Inventor: BINDU RAMA RAO, LAGUNA NIGUEL, CA (US)

(21) Appl. No.: 15/277,226

(22) Filed: Sep. 27, 2016

(51) Int. Cl. H02J 7/00; H05K 7/20

(52) U.S. Cl. CPC H02J 7/0044; H05K 7/20145; H05K 7/20172; H02J 7/0068

(57) ABSTRACT

A power bank charger comprising a fan component mounted on one of the multiple surfaces that generates cooling airflow, wherein the fan component is electrically connected to the discharging unit of the power bank charger through a fan connector. The housing of the power bank charger comprises ridges on the outer surfaces of the housing for guiding airflow in order to cool the power bank charger. The housing comprises ridges internally on the outer surfaces of the housing for additional cooling airflow. The microcontroller in the power bank charger controls the charging of the plurality of electronic devices plugged into corresponding ones of a plurality of output connectors, based on their current power status, and based on a priority of charging of various types of electronic devices.

### CROSS REFERENCES TO RELATED APPLICATIONS

### Background

### 1. Technical Field

The present invention relates generally to recharging of electronic devices, and more specifically to power bank and other similar power charging units for mobile electronic devices.

### 2. Related Art

Mobile devices are becoming ubiquitous. Children carry them and so do adults. Children use them to ask their parents to come pick them up at a mall or a park. Mobile devices consume a lot of power from their batteries and often they have to be recharged frequently.

People buy power banks to recharge mobile devices. Some power banks need to be charged separately and then used to recharge mobile devices. Power banks get warm/heated while they are being recharged, and this is sometimes a concern to users. Power banks also become warm sometimes while they are discharged while charging other devices. Such heating of power banks or other devices they charge is sometimes a serious concern. There are no easy solutions for solving this problem.

Further limitations and disadvantages of conventional and traditional approaches will become apparent to one of ordinary skill in the art through comparison of such systems with the present invention.

### BRIEF SUMMARY OF THE INVENTION

The present invention is directed to apparatus and methods of operation that are further described in the following Brief Description of the Drawings, the Detailed Description of the Invention, and the claims. Other features and advantages of the present invention will become apparent from the following detailed description of the invention made with reference to the accompanying drawings.

### BRIEF DESCRIPTION OF THE DRAWINGS

FIG. 1 is a perspective block diagram of a power bank charger that powers other electronic devices when connected with power cables. The power bank charger comprises a microcontroller unit and a power bank charging unit electrically connected to the microcontroller unit; and

FIG. 2 is a perspective block diagram of a power bank charger that powers other electronic devices when connected with power cables.

### DETAILED DESCRIPTION OF THE DRAWINGS

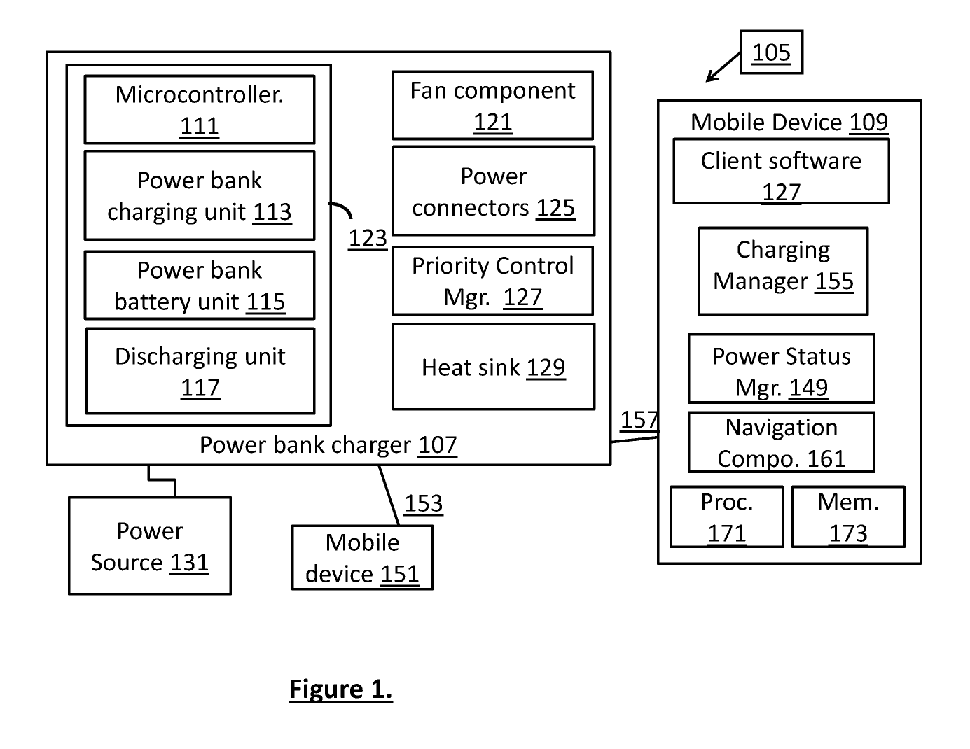

FIG. 1 is a perspective block diagram of a power bank charger 107 that powers other electronic devices 109 when connected with power cables. The power bank charger 107 comprises a microcontroller unit 111 and a power bank charging unit electrically connected to the microcontroller unit. The power bank charging unit 113 is adapted for receiving power from a power source 131. The power bank charger 107 also comprises a power bank battery unit 115 electrically connected to the microcontroller unit 111 and the power bank charging unit 113 so that the power bank battery unit 115 is charged by the power received from the power source 131, and a discharging unit 117 electrically connected to the power bank charging unit 113 and the power bank battery unit 115. The discharging unit 117 is adapted for connecting to one or more of a plurality electronic devices 109 via a plurality of power connectors, so that the power is provided to the one or more of the plurality of electronic devices 109.

The power bank charger 107 also comprises a housing 123 with ridges on the outer surfaces for air flow, to cool the power bank charger. The housing 123 also comprising ridges internally on the outer surfaces for additional cooling airflow. The outer surfaces of the housing 123 comprises multiple surfaces, wherein at least one surface of the multiple surfaces provides airflow exit and at least another surface of the multiple surfaces provides airflow entrance.

The power bank charger 107 also comprises a fan component 121 attached to one of the multiple surfaces and electrically connected to the discharging unit 117 to generate cooling airflow. The fan component 121 is internally attached (inside the housing) in one configuration, and externally attached in another.

In one configuration, the fan component 121 is mounted externally to the power bank charger 107 on one of the multiple surfaces. In a related configuration, the fan component 121 is attached to the outer housing and the fan component 121 is plugged into the power bank charger 107, by means of one of the plurality of power connectors 125. In yet another configuration, the one of the plurality of power connectors 125 used to plug the fan component 121 is a 3-pin power connector.

In one configuration, the power provided from the power source 131 is directly applied to the one or more of the plurality of electronic devices 109, 151 through the power bank charging unit 113 and the discharging unit 117, for charging the one or more of the plurality of electronic devices 109, 151.

In one embodiment of the power bank charger 107, at least one of the multiple surfaces is also employed as a heat sink 129.

The microcontroller 111 manages the power delivery to the plurality of electronic devices 109, 151 plugged into the plurality of power connectors 125 based on a priority and a current power status of the plurality of electronic devices 109, 151. A priority control manager 127 facilitates determination of priority for the various electronic devices currently plugged in, determination of current power status of these various electronic devices plugged in, etc. It then determines how and when power should be provided to the various electronic devices 109, 151 plugged in. For example, in one scenario it determines that mobile device 109 should not be powered/. Charged as it has sufficient power levels, and instead mobile device 151 needs to be charged. For example, this is because mobile device 151 has only 10% power left (power status) and is more important in its user specified priority/power status. Other criteria for assigning priorities are also contemplated.

In another configuration of a power bank charger 107 that powers other electronic devices 109, 151 when connected with power cables 157, 153, the power bank charger 107 comprises the microcontroller 111, the power bank charging unit 113 electrically connected to the microcontroller unit 111, adapted for receiving power from a power source 131, and a power bank battery unit 115 electrically connected to the microcontroller unit 111 and the power bank charging unit 113 that gets charged by power received from the power source 131. The power bank charger 107 also comprises the discharging unit 117 electrically connected to the power bank battery unit 115 and the power bank charging unit 113 that is configured to supply power to a plurality of electronic devices 109, 151 plugged into corresponding ones of a plurality of output connectors 125, and the housing 123 comprising multiple surfaces wherein at least one surface of the multiple surfaces provides airflow exit and at least another surface of the multiple surfaces provides airflow entrance. The power bank charger 107 comprises the fan component 121 mounted on one of the multiple surfaces that generates cooling airflow, wherein the fan component 121 is electrically connected to the discharging unit 117 through a fan connector.

The housing comprises ridges on the outer surfaces of the housing for guiding airflow in order to cool the power bank charger. The housing comprises ridges internally on the outer surfaces of the housing for additional cooling airflow. The microcontroller controls the charging of the plurality of electronic devices plugged into corresponding ones of a plurality of output connectors, based on their current power status, and based on a priority of charging of various types of electronic devices. In another configuration of the power bank charger, the microcontroller controls the charging of the plurality of electronic devices plugged into corresponding ones of a plurality of output connectors, based on their current power status and user preferences.

In another related configuration, the fan component 121 is electrically connected to the discharging unit 117 through one of the plurality of output connectors 125.

The mobile device 109 comprises a client software 127 that helps manipulate charging and power management when the mobile device 109 is charged on the go, and used on the go, by a user. It also provides user interaction screens to manage power consumption and charging control, etc. The mobile device 109 comprises a charging manager 155 that also manages priority assignment for charging purposes, and other charging related activities, including monitoring of charging events, and a power status manager 149 that monitors power usage by various applications, various hardware units, and over power status in the mobile device 109.

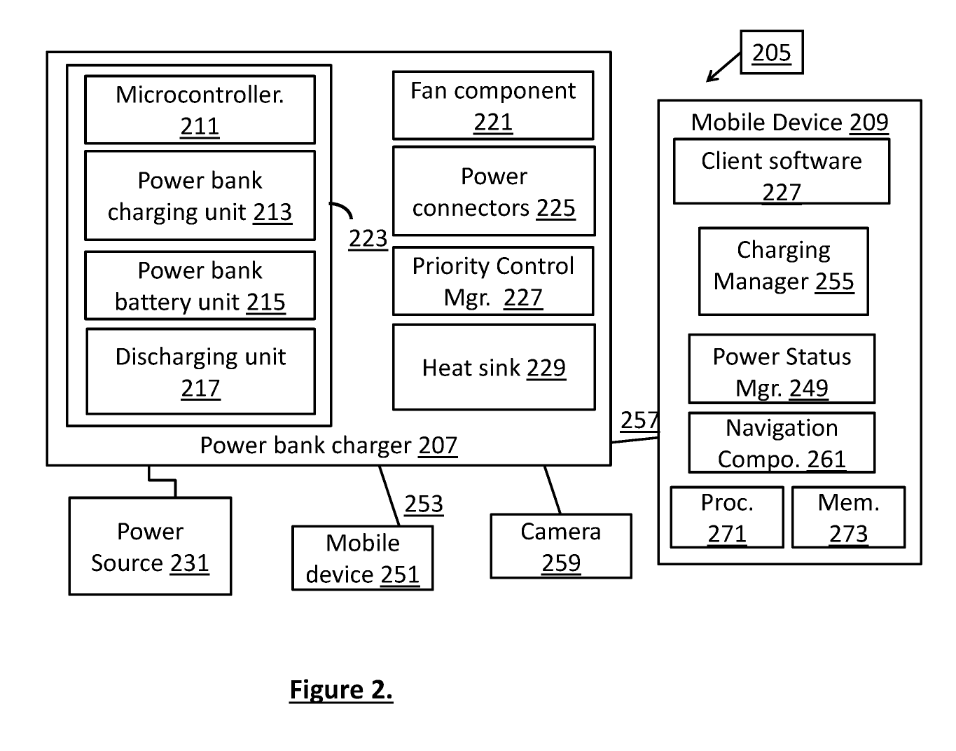

FIG. 2 is a perspective block diagram of a power bank charger 207 that powers other electronic devices 251, 209 when connected with power cables 257, 253. The power bank charger 207 comprises a microcontroller 211 and a power bank charging unit 213 electrically connected to the microcontroller unit 211, adapted for receiving power from a power source 231. It also comprises a power bank battery unit 215 electrically connected to the microcontroller unit 211 and the power bank charging unit 213 that gets charged by power received from the power source 231, and a discharging unit 217 electrically connected to the power bank battery unit 215 and the power bank charging unit 213 that is configured to supply power to a plurality of electronic devices 209, 251 plugged into corresponding ones of a plurality of output connectors 225. The power bank charger 207 comprises a housing 223 comprising multiple surfaces wherein at least one surface of the multiple surfaces provides airflow exit and at least another surface of the multiple surfaces provides airflow entrance. The power bank charger 207 comprises a fan component 221 mounted on one of the multiple surfaces that generates cooling airflow, wherein the fan component 221 is electrically connected to the discharging unit 217 through a fan connector. The housing 223 comprises ridges on the outer surfaces of the housing 223 for guiding airflow in order to cool the power bank charger 207.

The fan component 221 is mounted externally on the housing 223 in one embodiment, and internally to the housing 223 in another embodiment. The fan component 221 is provided as an accessory that is clamped/attached to the power bank charger 207 in another embodiment, where the fan component 221 (accessory) is plugged into one of the output connectors 225 (such as YSB or 3-point connector) provided by the power bank charger 207.

In one configuration, the power bank charger 207 comprises the fan component 221 mounted on one of the multiple surfaces that generates cooling airflow, wherein the fan component 221 is electrically connected to the discharging unit 217 of the power bank charger 207 through a fan connector 221. The housing 223 of the power bank charger 207 comprises ridges on the outer surfaces of the housing for guiding airflow in order to cool the power bank charger 207. The housing 223 comprises ridges internally on the outer surfaces of the housing 223 for additional cooling airflow. The microcontroller 211 in the power bank charger 207 controls the charging of the plurality of electronic devices 209, 251 plugged into corresponding ones of a plurality of output connectors 225, based on their current power status, and based on a priority of charging of various types of electronic devices 209, 251, 259.

Electronic devices that are charged by the power bank charger 207 include the mobile device 209 which is a mobile phone, a cell phone, a satellite phone, etc., the mobile device 251 which is a tablet/ipad/display unit, and a camera 259. Other types of electronic devices are also contemplated. These devices 209, 251, 259 are charged based on a priority in one embodiment, and based on their current power status in another, etc.

In one embodiment of the present invention, a cooling system for a power bank charger 207 is clamped onto (or otherwise attached) to the power bank charger 207. The power bank charger 207 powers other electronic devices 209, 251, 259 when connected with power cables 253, 257. The cooling system comprises a fan component 221 mounted on one of the multiple surfaces of the power bank charger that generates cooling airflow, wherein the fan component 221 is electrically connected to the power bank charger 207 unit through a fan connector. The cooling system is such that the fan component 221 is clamped onto one of the surfaces of the power bank charger 207. In a related embodiment, the fan component 221 is electrically connected to the power bank charger 207 through a USB connector (one of the power connectors 225) provided by the power bank charger 207.

The power bank charger of claim further comprises a priority control manager 227 that determines a priority of charging for one or more of the electronic devices 209, 251, 259 currently connected to the power bank charger 207 for charging purposes. The priority control manager 227, based on the priority of charging, causes the microcontroller 211 to instruct the discharging unit 217 to power the charging of one of the electronic devices 209, 251, 259.

In another related configuration, the power bank charger 207 further comprises the priority control manager 227 that determines a priority of charging one or more of the electronic devices 209, 251, 259 currently connected to the power bank charger 207 for charging purposes, and the priority control manager 227, based on the priority of charging, causes the microcontroller 211 to instruct the discharging unit 217 to power the charging of one of the electronic devices 209, 251, 259 in a specific order and according to a specific charging ratio. For example, the mobile device 209 is charged first upto 50% of its power capacity, based on the fact that it is running very low on its battery power (relative to others), and subsequently the camera 259 is charged simultaneously with the mobile device 251 because the camera is already at 80% charging capacity and the mobile device 251 is already at 70% capacity. Similarly, for example, the current levels drawn by individual electronic devices is also factored in in addition to percentage of charging capacity of each of the electronic devices 209, 251, 259 currently plugged in.

As one of ordinary skill in the art will appreciate, the terms “operably coupled” and “communicatively coupled,” as may be used herein, include direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled” and “communicatively coupled.”

Although the present invention has been described in terms of electronic devices such as mobile phones and computers, it must be clear that the present invention also applies to other types of devices including mobile devices, laptops with a browser, tablets, cellular phones, game controllers, a hand held device such as a PDA, a television, a set-top-box, a media center at home, robots, robotic devices, vehicles capable of navigation, and a computer communicatively coupled to the network.

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention.

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

What is claimed is:

1. A power bank charger that powers other electronic devices when connected with power cables, the power bank charger comprising:
a microcontroller unit;
a power bank charging unit electrically connected to the microcontroller unit, adapted for receiving power from a power source;
a power bank battery unit electrically connected to the microcontroller unit and the power bank charging unit so that the power bank battery unit is charged by the power received from the power source;
a discharging unit electrically connected to the power bank charging unit and the power bank battery unit, adapted for connecting to one or more of a plurality electronic devices via a plurality of power connectors, so that the power is provided to the one or more of the plurality of electronic devices;
a housing with ridges on the outer surfaces for air flow, to cool the power bank charger;
the housing also comprising ridges internally on the outer surfaces for additional cooling airflow;
wherein the outer surfaces of the housing comprises multiple surfaces, wherein at least one surface of the multiple surfaces provides airflow exit and at least another surface of the multiple surfaces provides airflow entrance; and
a fan component attached to one of the multiple surfaces and electrically connected to the discharging unit to generate cooling airflow.

2. The power bank charger of claim 1 wherein the fan component is mounted externally to the power bank charger on one of the multiple surfaces.

3. The power bank charger of claim 1 wherein power provided from the power source is directly applied to the one or more of the plurality of electronic devices through the power bank charging unit and the discharging unit, for charging the one or more of the plurality of electronic devices.

4. The power bank charger of claim 1 wherein the fan component is attached to the outer housing and the fan component is plugged into the power bank charger, by means of one of the plurality of power connectors.

5. The power bank charger of claim 4 wherein the one of the plurality of power connectors used to plug the fan component is a 3-pin power connector.

6. The power bank charger of claim 1 wherein at least one of the multiple surfaces is also employed as a heat sink.

7. The power bank charger of claim 1 the microcontroller manages the power delivery to the plurality of electronic devices plugged into the plurality of power connectors based on a priority and a current power status of the plurality of electronic devices.

8. A power bank charger that powers other electronic devices when connected with power cables, the power bank charger comprising:
a microcontroller;
a power bank charging unit electrically connected to the microcontroller unit, adapted for receiving power from a power source;
a power bank battery unit electrically connected to the microcontroller unit and the power bank charging unit that gets charged by power received from the power source;
a discharging unit electrically connected to the power bank battery unit and the power bank charging unit that is configured to supply power to a plurality of electronic devices plugged into corresponding ones of a plurality of output connectors;
a housing comprising multiple surfaces wherein at least one surface of the multiple surfaces provides airflow exit and at least another surface of the multiple surfaces provides airflow entrance; and
a fan component mounted on one of the multiple surfaces that generates cooling airflow, wherein the fan component is electrically connected to the discharging unit through a fan connector.

9. The power bank charger of claim 8 wherein the housing comprises ridges on the outer surfaces of the housing for guiding airflow in order to cool the power bank charger.

10. The power bank charger of claim 8 wherein the housing comprises ridges internally on the outer surfaces of the housing for additional cooling airflow.

11. The power bank charger of claim 8 wherein the microcontroller controls the charging of the plurality of electronic devices plugged into corresponding ones of a plurality of output connectors, based on their current power status, and based on a priority of charging of various types of electronic devices.

12. The power bank charger of claim 8 wherein the microcontroller controls the charging of the plurality of electronic devices plugged into corresponding ones of a plurality of output connectors, based on their current power status and user preferences.

13. The power bank charger of claim 8 wherein the fan component wherein the fan component is electrically connected to the discharging unit through one of the plurality of output connectors.

14. The power bank charger of claim 8 further comprising:
a priority control manager that determines a priority of charging one or more of the electronic devices currently connected to the power bank charger for charging purposes;
the priority control manager, based on the priority of charging, causes the microcontroller to instruct the discharging unit to power the charging of one of the electronic devices.

15. The power bank charger of claim 8 further comprising:
a priority control manager that determines a priority of charging one or more of the electronic devices currently connected to the power bank charger for charging purposes;
the priority control manager, based on the priority of charging, causes the microcontroller to instruct the discharging unit to power the charging of one of the electronic devices in a specific order and according to a specific charging ratio.

16. A cooling system for a power bank charger, wherein the power bank charger powers other electronic devices when connected with power cables, the cooling system comprising:
a fan component mounted on one of the multiple surfaces of the power bank charger that generates cooling airflow, wherein the fan component is electrically connected to the power bank charger unit through a fan connector.

17. The cooling system of claim 14 wherein the fan component is clamped onto one of the surfaces of the power bank charger.

18. The cooling system of claim 14 wherein the fan component is electrically connected to the power bank charger through a USB connector provided by the power bank charger.
